(19) United States
(12) Patent Application Publication
(10) Pub. No.: US 2025/0133896 A1
(43) Pub. Date: Apr. 24, 2025

(54) ORGANIC ELECTROLUMINESCENT DEVICES

(71) Applicant: Universal Display Corporation, Ewing, NJ (US)

(72) Inventors: Michael HACK, Carmel, CA (US); Michael Stuart WEAVER, Princeton, NJ (US); Nicholas J. THOMPSON, New Hope, PA (US)

(21) Appl. No.: 18/911,852

(22) Filed: Oct. 10, 2024

Related U.S. Application Data
(60) Provisional application No. 63/592,659, filed on Oct. 24, 2023.

(51) Int. Cl. H10K 50/115; H10K 50/822; H10K 102/00

(52) U.S. Cl. CPC H10K 50/115; H10K 50/822; H10K 2102/351

(57) ABSTRACT

Embodiments of the disclosed subject matter provide a device including a plasmonic phosphorescent organic light emitting device (PHOLED) having an anode and a cathode having a thickness of about 5-100 nm. An emissive stack is disposed between the anode and the cathode and configured to produce excitons, and having a phosphorescent first emissive layer comprising an organic phosphorescent first emissive material. The device includes an enhancement layer comprising a plasmonic material exhibiting a surface plasmon resonance that non-radiatively couples to at least the organic phosphorescent first emissive material and transfers excited state energy from the first emissive material to non-radiative modes of the plasmonic material. The device is configured to generate less than 1° C. rise in Temp for every 2.26 mW/cm² of operating power applied to the device.

### CROSS-REFERENCE TO RELATED APPLICATIONS

This application claims priority to U.S. Patent Application Ser. No. 63/592,659, filed Oct. 24, 2023, the entire contents of which are incorporated herein by reference.

### FIELD

The present invention relates to emissive devices including organic emissive devices, including a plasmonic phosphorescent organic light emitting devices (PHOLED), and techniques for fabricating the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent molecules capable of phosphorescent emission is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art. Another application for phosphorescent molecules capable of phosphorescent emission is to make a lighting or illumination panel configured to emit monochrome, white, or color tunable light.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; a “yellow” layer, material, region, or device refers to one that has an emission spectrum with a peak wavelength in the range of about 540-600 nm; a “cyan” layer, material, or device refers to one that emits or has an emission spectrum with a peak wavelength in the range of about 490-520 nm; and an “orange” layer, material, or device refers to one that emits or has an emission spectrum with a peak wavelength in the range of about 570-620 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” or “dark blue” component has a peak emission wavelength in the range of about 400-470 nm, though these ranges may vary for some configurations. A “light green” component has a peak emission wavelength in the range of about 520-560 nm, and a “deep green” or “dark green” component has a peak emission wavelength in the range of about 500-520 nm, though these ranges may vary for some configurations. A near infrared (“NIR”) component has a peak emission wavelength in the range of about 700-1800 nm. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon the spectrum of light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red, green, or yellow light, such that a complete emissive stack or sub-pixel emits the red, green, or yellow light. In this case the initial emissive material or layer may be referred to as a “blue” component, even though the sub-pixel is a “red”, “green”, or “yellow” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373l, 0.6245]; [0.6270, 0.3725]; |
| | Interior: [0.3700, 0.4087]; [0.2886, 0.4572] |

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and the cathode. According to an embodiment, the organic light emitting device is incorporated into one or more device selected from a consumer product, an electronic component module, and/or a lighting panel.

According to an embodiment, a device may include a plasmonic phosphorescent organic light emitting device (PHOLED) having an anode and a cathode having a thickness of about 5-100 nm. The device may include an emissive stack disposed between the anode and the cathode and configured to produce excitons, the emissive stack having a phosphorescent first emissive layer comprising an organic phosphorescent first emissive material. The device may include an enhancement layer comprising a plasmonic material exhibiting a surface plasmon resonance that non-radiatively couples to at least the organic phosphorescent first emissive material and transfers excited state energy from the first emissive material to non-radiative modes of the plasmonic material. The device may be configured to generate less than 1° C. rise in temperature for every 2.26 mW/cm² of operating power applied to the device.

The plasmonic material of the enhancement layer may exhibit a surface plasmon resonance that non-radiatively couples to at least the phosphorescent first emissive material and transfers excited state energy from the first emissive material to the surface plasmon resonance of the plasmonic material.

The common enhancement layer may be disposed less than a threshold distance away from the organic phosphorescent first emissive material.

The enhancement layer may be disposed less than a threshold distance away from the organic phosphorescent first emissive material. The organic phosphorescent first emissive material may have a total non-radiative decay rate constant k_{non-rad}⁰, a total radiative decay rate constant k_{rad}⁰, a total non-radiative decay rate constant due to the enhancement layer k_{non-rad}^{plasmon}, and a total radiative decay rate constant due to the enhancement layer k_{rad}^{plasmon}. The enhancement layer is disposed not more than a threshold distance from the phosphorescent first emissive layer. The threshold distance may be a distance at which

$$\frac{{k}_{rad}^{plasmon}}{{k}_{non - rad}^{plasmon}} = \frac{{k}_{rad}^{0}}{{k}_{non - rad}^{0}} .$$

In the device, INC*OUTC>1−INC, where INC may be the fraction of excitons generated in the at least one emissive layer of the emissive stack that couple to one or more plasmon modes in the cathode, and OUTC may be the fraction of plasmons outcoupled as photons emitted outside of the emissive stack.

In the device, INC may be the number of excitons from the emissive layer of the emissive stack coupled to the plasmon mode in the cathode divided by the total number of excitons in the emissive layer of the emissive stack, and the OUTC may be the number of plasmons outcoupled to photons outside of the emissive stack divided by the total number of excitons in the emissive layer of the emissive stack.

The cathode of the device may include a film of Ag, where the thickness of the cathode is 5 nm-45 nm.

The device may be configured to generate not more than a 5° C. rise in operating temperature when operating at a power density of 11.4 mW/cm² or 13.6 mW/cm².

The device may be a display, and the plasmonic PHOLED may be configured to have not more than a 1° C. rise in operating temperature for a luminance of 268 nits increase in display luminance, or 320 nits increase in display luminance.

The device may include an outcoupling layer.

The device may be a display and may be configured to operate at a white point luminance of greater than 1,340 nits, greater than 1,400 nits, greater than 1,500 nits, and/or greater than 1,600 nits.

The emissive stack of the device may include at least two emissive layers disposed over one another.

The device may have INC 80%, where INC may be the fraction of excitons generated in the at least one emissive layer of the emissive stack that couple to one or more plasmon modes in the cathode.

The device may have INC 60%, where INC may be the fraction of excitons generated in the at least one emissive layer of the emissive stack that couple to one or more plasmon modes in the cathode.

The emissive stack may be configured to have a first peak photon density inside of the emissive stack that is lower than a second peak photon density outside of the emissive stack when the device is emitting light. The first peak photon density inside of the emissive stack may be lower than half of the second peak photon density outside of the emissive stack.

An external quantum efficiency of the plasmonic PHOLED of the device may be greater than 35%.

A first emissive layer of the at least one emissive layer of the device may have an excited state duration that is selected from the group consisting of: less than 20%, less than 25%, less than 30%, less than 35%, less than 40%, less than 45%, less than 50%, less than 55%, or less than 60% than a predetermined excited state lifetime value.

A difference between the plasmonic PHOLED that is configured to have external quantum efficiency of greater than 35% and an excited state lifetime that is selected from the group consisting of: less than 20%, less than 25%, less than 30%, less than 35%, less than 40%, less than 45%, less than 50%, less than 55%, or less than 60% than a predetermined excited state lifetime value.

The emissive stack of the plasmonic PHOLED may have at least a first side and a second side, where the device may be configured to emit light from the first side and may be configured to have a Lambertian emission profile of light.

The anode of the emissive stack may be transparent. The device may have an optical transparency of greater than 40% or greater than 60% across a visible spectrum.

The anode of the emissive stack may be reflective.

The plasmonic PHOLED of the device may have an external quantum efficiency that is greater than 35%, and has an incoupling of excitons from the at least one emissive layer to plasmon modes in the cathode that is greater than 60%. The anode of the device may be reflective.

The device may be a lighting panel and/or a full color display.

The cathode of the device may have a thickness of 5-200 nm, 5-150 nm, 5-100 nm, 5-75 nm, 5-60 nm, 5-45 nm, 15-45 nm, and/or 25-35 nm.

The device may be configured to generate less than 1° C. rise in temperature for every 2.72 mW/cm² of operating power applied to the device.

According to an embodiment, a consumer electronic device may include a plasmonic phosphorescent organic light emitting device (PHOLED) having an anode and a cathode having a thickness of about 5-100 nm. The consumer electronic device may include an emissive stack disposed between the anode and the cathode and configured to produce excitons, the emissive stack having a phosphorescent first emissive layer comprising an organic phosphorescent first emissive material. The consumer electronic device may include an enhancement layer comprising a plasmonic material exhibiting a surface plasmon resonance that non-radiatively couples to at least the organic phosphorescent first emissive material and transfers excited state energy from the first emissive material to non-radiative modes of the plasmonic material. The consumer electronic may be configured to generate less than 1° C. rise in Temp for every 2.26 mW/cm² of operating power applied to the device.

The consumer electronic device may be at least one of a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, an automotive display, a video walls comprising multiple displays tiled together, a theater or stadium screen, and/or a sign.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows a plot of a calculation of a photon ratio outside to inside the device as a function of an incoupling fraction for two different outcoupling efficiencies according to embodiments of the disclosed subject matter.

FIG. 4 is a plot showing dependency of plasmon to photon outcoupling efficiency versus incoupling to meet performance criteria of (a) peak photon density greater outside the organic stack and (b) external quantum efficiency (EQE) >35% according to embodiments of the disclosed subject matter.

FIG. 5 is a plot showing the calculated outcoupling efficiency to meet either of the two following conditions as a function of incoupling efficiency: (1) EQE>35% or (2) more photons outside the device than inside the device according to embodiments of the disclosed subject matter.

FIG. 6 shows the photon density both inside and outside device versus incoupling efficiency for two different outcoupling efficiencies according to embodiments of the disclosed subject matter.

FIG. 7 shows a qualitative plot of the radiative decay rate constant due to the surface plasmon polariton (SPP) mode and the non-radiative decay rate constant due to the SPP mode as a function of distance of the light emitting material from the metallic film according to embodiments of the disclosed subject matter. FIG. 7 also shows a plot of the ratio of the total radiative to non-radaitive rate constant for the system as a function of distance of the light emitting material from the metallic film which is dominated by the rate constants due to the SPP mode according to embodiments of the disclosed subject matter.

FIG. 8 shows a plot of quantum yield as a function of light emitting material's distance from the metallic enhancement film with two threshold distances identified according to embodiments of the disclosed subject matter.

FIG. 9 shows an example plasmonic phosphorescent organic light emitting device (PHOLED) according to embodiments of the disclosed subject matter.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

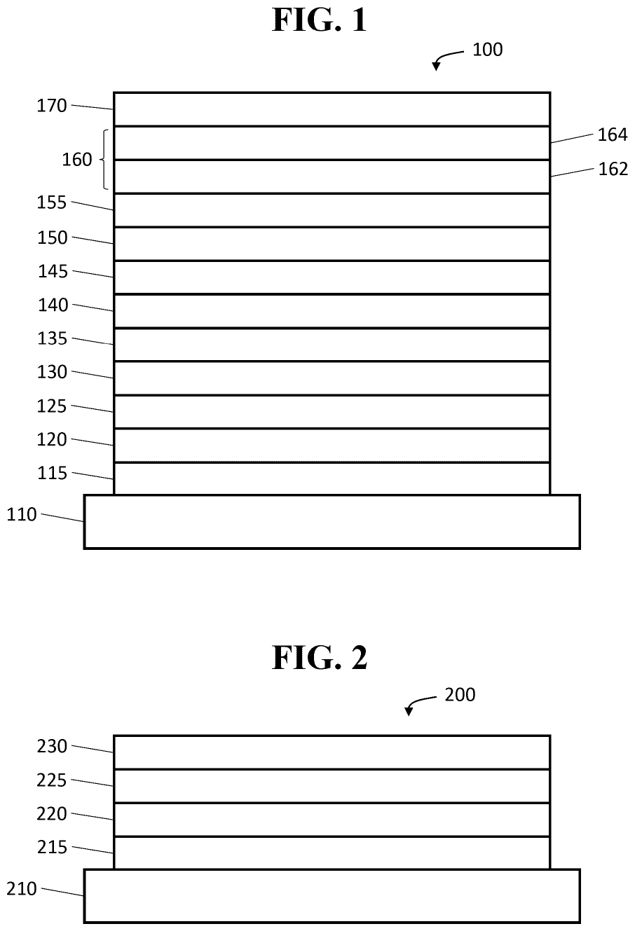

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. Barrier layer 170 may be a single- or multi-layer barrier and may cover or surround the other layers of the device. The barrier layer 170 may also surround the substrate 110, and/or it may be arranged between the substrate and the other layers of the device. The barrier also may be referred to as an encapsulant, encapsulation layer, protective layer, or permeation barrier, and typically provides protection against permeation by moisture, ambient air, and other similar materials through to the other layers of the device. Examples of barrier layer materials and structures are provided in U.S. Pat. Nos. 6,537,688, 6,597,111, 6,664,137, 6,835,950, 6,888,305, 6,888,307, 6,897,474, 7,187,119, and 7,683,534, each of which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers as described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. The emissive layer may use different emissive display technologies. Such technologies may include inorganic and/or organic devices, such as LEDs, mini LEDs, microLEDs, thin electroluminescent films, organic light emitting devices, and the like. An “emissive layer” or “emissive material” as disclosed herein may include an organic emissive material and/or an emissive material that contains quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be placed, disposed, or deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution-based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, where the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the enhancement layer comprises a plasmonic material exhibiting a surface plasmon resonance that non-radiatively couples to at least the phosphorescent first emissive material and transfers excited state energy from the first emissive material to the surface plasmon resonance of the plasmonic material. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. Outcoupling methods for the substrate mode or waveguiding modes include but are not limited to lens, diffusers, and buried diffractive elements. In some embodiments, one or more intervening layer can be disposed between the enhancement layer and the outcoupling layer. The examples for intervening layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles where the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

In embodiments of the disclosed subject matter, a device may include an enhancement layer that is disposed over an emissive area of at least one sub-pixel that is configured to have a Lambertian emission and/or at least one sub-pixel having a microcavity configured for direct emission, as described in detail below. In at least some of such embodiments, the enhancement layer may include a plasmonic structure that is disposed a predetermined threshold distance from the emissive area. The predetermined threshold distance may be a distance at which a total non-radiative decay rate constant is equal to a total radiative decay rate constant. In some of such embodiments, device may include an outcoupling layer is disposed over the enhancement layer on the opposite side of the emissive area.

It is believed that the internal quantum efficiency (IQE) of fluorescent OLEDs can exceed the 25% spin statistics limit through delayed fluorescence. As used herein, there are two types of delayed fluorescence, i.e., P-type delayed fluorescence and E-type delayed fluorescence. P-type delayed fluorescence is generated from triplet-triplet annihilation (TTA).

In some embodiments, a compound in an emissive material and/or layer in an OLED may be used as a phosphorescent sensitizer, where one or multiple layers in the OLED may include an acceptor in the form of one or more fluorescent and/or delayed fluorescence emitters. In some embodiments, the compound can be used as one component of an exciplex to be used as a sensitizer. As a phosphorescent sensitizer, the compound may be capable of energy transfer to the acceptor, and the acceptor may emit the energy or further transfer energy to a final emitter. The acceptor concentrations may range from 0.001% to 100%. The acceptor may be in either the same layer as the phosphorescent sensitizer or in one or more different layers. In some embodiments, the acceptor may be a TADF emitter. In some embodiments, the acceptor may be a fluorescent emitter. In some embodiments, the emission may arise from any or all of the sensitizer, acceptor, and/or final emitter.

On the other hand, E-type delayed fluorescence described above does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small AES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, an automotive display, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer having carbon nanotubes.

In some embodiments, the OLED further comprises a layer having a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound causing light to be generated can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes, including phosphor sensitized fluorescence.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety. Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

Key parameters for OLED devices may be efficiency and operational lifetime. In recent years, plasmonic OLEDs have been proposed, where excitons in the organic stack of the plasmonic OLED may be quenched by conversion to plasmon polaritons in an appropriate cathode metal and subsequently re-emitted as photons by an outcoupler, such as a nanoparticle-based array on top of a dielectric spacer. This type of device may have additional benefits, such as Lambertian emission, which may reduce color shifts and has less luminance roll-off with viewing angle.

For the device to be viable from a product requirements perspective, both the excited state lifetime may be reduced to extend the operational lifetime of the device, and the external quantum efficiency may meet or exceed that a conventional device (>35% for a phosphorescent OLED with a single emissive layer). Embodiments of the disclosed subject matter provide plasmonic phosphorescent organic light emitting devices (PHOLEDs) based on reducing the exciting state lifetime by at least a factor of 2.5 (which may result in a greater than a six (6) times increase in operational lifetime) and with an EQE (external quantum efficiency) exceeding 35%.

In embodiments of the disclosed subject matter, the device may include an emissive layer that comprises materials that have emissions via one or more of: phosphorescence, fluorescence, thermally activated delayed fluorescence, i.e., TADF (also referred to as E-type delayed fluorescence), triplet-triplet annihilation, or combinations of these processes, including phosphor sensitized fluorescence. Additionally, embodiments of the disclosed subject matter may include one or more emissive layers, and each of these one or more emissive layers comprises materials that have emissions via one or more of: phosphorescence, fluorescence, thermally activated delayed fluorescence, i.e., TADF (also referred to as E-type delayed fluorescence), triplet-triplet annihilation, or combinations of these processes, including phosphor sensitized fluorescence. In embodiments that include more than two emissive layers, each emissive layer of the more than two emissive layers may comprise materials that emit via the same emission processes, some of the same emission processes, or none of the same emission processes. In embodiments of the present invention, the device may include an emissive layer that includes inorganic emissive materials including, but not limited to, as LEDs, mini LEDs, microLEDs, and the like.

In embodiments of the disclosed subject matter, plasmon polaritons and plasmon-exciton-polaritons may be used to reduce the excite state duration and/or provide stability. This may reduce the excited state density in an emissive layer (EML) of the plasmonic PHOLED and increase the stability of the device. Stability increase may be non-linear on the reduction of excited state duration, which suggests that a reduction in excited state duration of 2.5 times (i.e., 2×) may provide a stability increase of more than six times (i.e., 6× increase).

With regards to the efficiency of the device, the most widely utilized application for OLED displays is the mobile phone display. A microcavity may be utilized in mobile phone displays to render saturated colors. The microcavity modifies the angular emission profile of the OLED. The emitted power may increase normal to a surface of the OLED and may decrease rapidly at angles other than normal to the surface. The spectrum of the OLED may change as a function of angle. These properties may be a detriment to wider OLED adoption. However, to replace microcavities, a plasmonic PHOLED may be used that has an efficiency such that light emitted normally from the plasmonic device has a similar efficiency to that normal incident light from a microcavity device. For a Lambertian emitting device, this would correspond to an EQE that is around 35% or higher for a device with a single emissive layer.

In conventional OLEDs that either use a microcavity structure or with OLEDs that do not use a microcavity, there may be loss pathways. Such loss pathways may include waveguiding of photons. In a conventional OLED, the photon number inside the devices is larger than the photon number outside of the device. However, due to excitons coupling to the surface plasmon polariton, the photon number inside of a plasmon device may be smaller than the photon number outside the device. Embodiments of the disclosed subject matter provide a device where a peak photon density outside the organic stack exceeds the peak photon density inside the organic stack in a normal direction to the substrate. This may be without the use of a lens coupled to a substrate, and/or without the use of a high refractive index substrate optically coupled to a high refractive index lens. The device of the disclosed embodiments may reduce exciton densities in the stack while radiating photons efficiently as useful light. In some circumstances, the peak photon density outside the organic stack may exceed double the peak photon density inside the organic stack in a normal direction to the substrate.

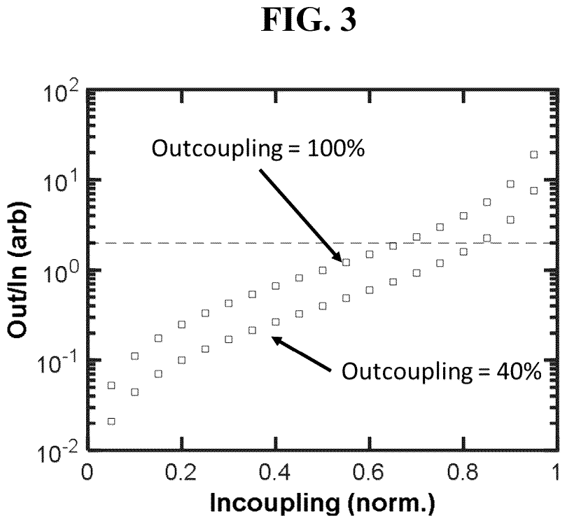

In a conventional bottom emitting device, the maximum photon number outside the device may be divided by the photon density inside the device. Assuming a nearly zero vertical dipole moment which provide the best dipole orientation for outcoupling light, approximately 50% of the photons may be outcoupled to light outside the device. There may be approximately 20% loss of excitons to the aluminum (Al) cathode and 5% loss to absorption. This means that approximately 25% of the light is trapped inside the device. In practice, exciton losses inside the stack may reduce the number of photons outcoupled from the device. As shown in FIG. 3, the photon number outside the device divided by the photon number inside the device may exceed ten (10) and may reach up to twenty (20) for the plasmonic PHOLED devices of the disclosed embodiments.

Losses in the device may take the form of reduced exciton density or reduced photon density. These losses may impact the ratio of photons outside the device to inside the device depending on the exact nature and position of these losses. Exciton losses in the stack may generally reduce the photon density both inside and outside the device, whereas photon losses in the stack may primarily reduce the photon density inside the device.

The excited state lifetime may be reduced by various means. For example, placing the EML close to a silver cathode may accomplish a reduction in excited state lifetime. Using the Purcell effect in a microcavity has also demonstrated a reduction in excited state lifetime.

These design criteria for embodiments of the disclosed subject matter may be derived from the following considerations, where INC may be the incoupling of excitons from the emissive layer (EML) to the plasmon modes in the cathode, and OUTC may be outcoupling of plasmons to photons outside of the organic stack, where the device EQE=INC*OUTC. In an embodiment, INC may be the number of excitons from the emissive layer of the emissive stack coupled to the plasmon mode in the cathode divided by the total number of excitons in the emissive layer of the emissive stack, and the OUTC may be the number of plasmons outcoupled to photons outside of the emissive stack divided by the total number of excitons in the emissive layer of the emissive stack.

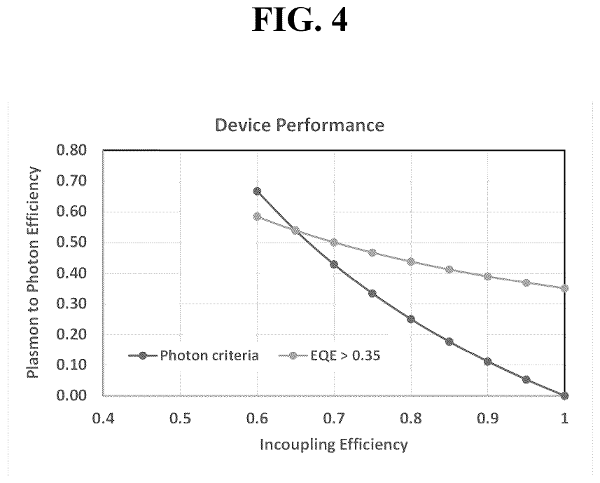

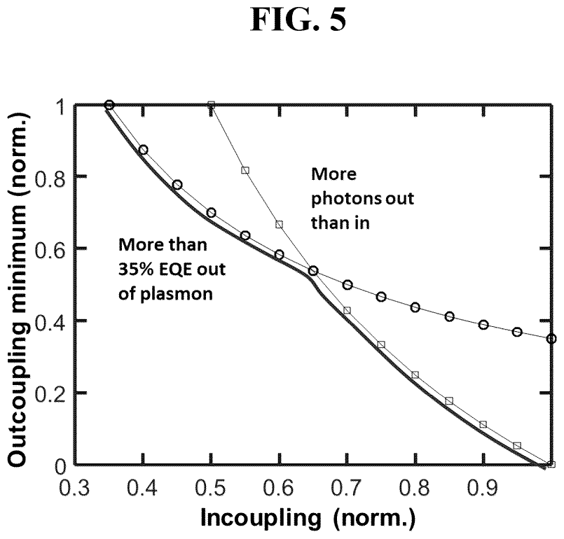

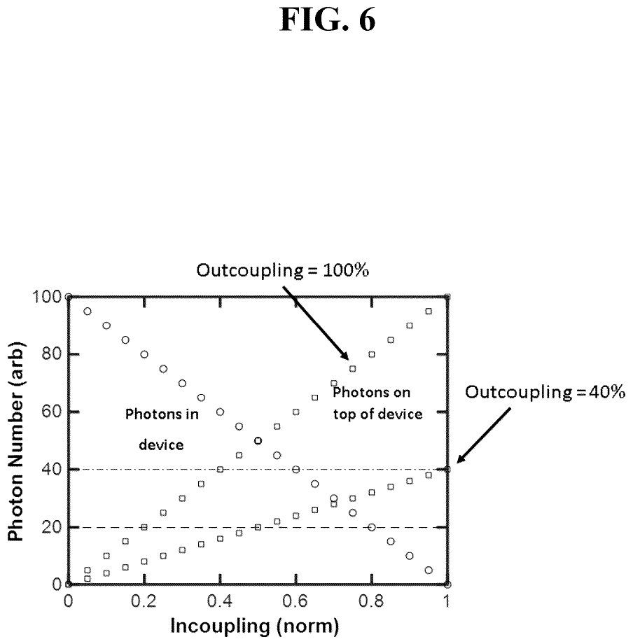

To ensure that the peak photon density outside the organic stack exceeds the peak photon density inside the organic stack in a normal direction to the substrate: INC*OUTC>1−INC. FIGS. 4-5 show plots relating device design parameters OUTC to INC to meet two device design criteria: (1) photon criteria where the peak photon density inside the organic stack may be lower than that outside the stack, and (2) INC>60% and EQE>35% for a device with a single emissive layer (EML).

The plasmonic PHOLEDs of the disclosed subject matter may lower device temperature rise for any given drive current as compared to a conventional PHOLED. The plasmonic PHOLEDs of the disclosed subject matter may have improved device performance and device lifetime by reducing the temperature increases when luminance increases. Reducing the operating temperature of a display is beneficial, as it may extend device operational lifetime.

In a conventional OLED, heat is generated in the organic stack between anode and cathode. This heat is related to (1−OUTCOUPLING) where OUTCOUPLING is the EQE. That is, heat may be related to the energy put into the device and not emitted as photons.

In a plasmonic PHOLED, heat may be generated by losses in two different and separate modes. Firstly, heat may be generated by losses in the organic stack between anode and cathode, which is related to (1−INC). That is, the energy may be put into the device, and may not be coupled into the cathode as plasmons.

Secondly, in a plasmonic PHOLED, heat may be generated by plasmon losses in both the cathode and an outcoupling layer. This may be because there is less than 100% efficiency in the outcoupling of plasmons, so this second loss will be related to INC*(1−OUTC). That is, the loss in stack is related to (1−INC), and the loss outside is related to INC*(1−OUTC). By way of consistency we can see that total losses is the sum of those inside and outside the organic stack is related to (1−OUTCOUPLING) where OUTCOUPLING=INC*OUTC which may be the same or similar to that of a conventional device except that in the plasmonic device the losses occur in two different regions of the device. Embodiments of the disclosed subject matter may reduce the temperature rise in a device for any given total loss. Heat loss in or above the cathode (i.e., outside of the organic stack) may be removed by the metal cathode that is configured to have a thickness to provide a thermal conductivity. Device stability may be strongly dependent on temperature. Reducing this temperature rise may greatly improve device operational lifetime.

To analyze the impact of the cathode on mitigating the temperature rise, results from laser flash analysis of thermal conductivity may be used. In this method, one side of the material may be heated by a pulse of heat (from a laser). The thermal conductivity may be determined by measuring the heat rise on the opposite side of the material. For one-dimensional diffusion, the following has been determined:

$$α = 0.139 * {d}^{2} / t \qquad ( 1 )$$

where α is the thermal diffusivity in cm²/s, d is the distance (thickness) of the sample, and t is the time for the temperature to reach % the ultimate value, which may be a steady state value. This equation may be re-cast to determine the time it would take an instantaneous amount of heat generation to leave the sub-pixel area.

Typical displays are 250-500 DPI, which means that a pixel is 100 to 50 micrometers wide. Although each pixel is typically formed of 3 sub-pixels, a single pixel is assumed in this example. This means that heat generated in the middle of the pixel would have to travel 50 to 25 micrometers to ‘escape’ the pixel and not increase the temperature of the OLED. Re-arranging equation (1), we find

$$that : t = 0.139 * {d}^{2} / α .$$

Using α=1.65 cm²/s for Ag, an instantaneous amount of heat may leave the typical display area in between 0.5 to 2.0 microseconds. This is very quick and suggests that heat generated in the cathode may not contribute to a temperature rise in the OLED device. One important aspect of this is that the Ag cathode is continuous, such that it exhibits a thermal diffusivity similar to bulk Ag. Typical Ag thins films may be continuous at a thicknesses as low as 3-5 nm with good adhesion layers. Thus, plasmonically active cathodes of devices of the disclosed subject matter may range in thickness from approximately 5 nm up to 200 nm, 5 nm up to 150 nm, 5 nm up to 100 nm, 5 nm up to 75 nm, 5 nm up to 60 nm, 5 nm up to 45 nm, 15 nm up to 45 nm, and may preferably range from 25 nm up to 35 nm for Ag.

As a Figure of Merit (FOM), the heat generated inside the stack of a plasmonic PHOLED compared to a conventional PHOLED at same drive current may be equal to (1−INC)/(1−OUTCOUPLING). The Table 1 below provides FOM percentages based on INC and OUTC percentages:

TABLE 1

| INC | OUTC | FOM |
|---|---|---|
| 60% | 60% | 63% |
| 70% | 60% | 52% |
| 70% | 70% | 59% |
| 80% | 60% | 38% |
| 80% | 70% | 45% |
| 80% | 80% | 56% |

Based on this analysis, embodiments of the disclosed subject matter provide a plasmonic PHOLED with INC>=80%. As compared to a non-plasmonic PHOLED display with EQE of <=40%, the heat rise in devices of the disclosed embodiments may be less than approximately half at any given current density, and at least less than 60% of the heat rise compared to a non-plasmonic PHOLED display with EQE of <=40%.

Given this relationship, plasmonic PHOLED displays of the disclosed subject matter may have high brightness and/or input power with low operational temperatures. For example, these calculations may be based on U.S. Pat. No. 8,766,531, which shows an input power of 35.3 mW/cm² causes an AMOLED display to increase its temperature by 26° C.

Embodiments of the disclosed subject matter provide devices with a maximum display temperature rise of 5° C. This may be based on an approximate 25% reduction in lifetime for every 5° C. increase in lifetime. This may be a reasonable limit to operational lifetime which will not cause a visual degradation of the display that may impact its use.

Assuming a temperature rise is linear with input power, 5° C. may correspond to less than 6.8 mW/cm² input power for a conventional PHOLED display. The plasmonic device of the disclosed subject matter may achieve the same rise in temperature with two times (2×) the input power, which may correspond to 13.6 mW/cm² for less than 5° C. operational temperature rise, assuming FOM <50%. The plasmonic device of the disclosed subject matter may achieve the same rise in temperature with 1.67 times the input power than the non-plasmonic device, which may correspond to 11.4 mW/cm² for less than 5° C. operational temperature rise, assuming FOM <60%.

Table 2 which shows a plasmonic PHOLED operating at 500 cd/m² white point consumes less than 4.4 mW/cm² display power. Using the analysis from the Table 2, for 13.6 mW/cm² to enable less than 5° C. temperature rise, this may correspond to approximately 1600 nits full display white point for FOM <50%. Using the analysis from the Table 2, for 11.4 mW/cm² to enable less than 5° C. temperature rise, this may correspond to approximately 1340 nits full display white point for FOM <60%.

TABLE 2

| Assumptions | | |
|---|---|---|
| Green component= | 61.1% | |
| Red component= | 32.6% | |
| Blue component= | 6.3% | |
| % pixel on | 100% | |
| Display Specs | | |
| Width | 11.5 | cm |
| Height | 5.31 | cm |
| Brightness | 500 | cd/m² |
| CALCS | | |
| Green brightness= | 3,273 | |
| Red brightness= | 1,746 | |
| Blue brightness= | 338 | |
| Green power | 0.085 | W |
| Red power | 0.117 | W |
| Blue power | 0.064 | W |
| Total Power | 0.267 | W |
| | 4.36 | mW/cm² |

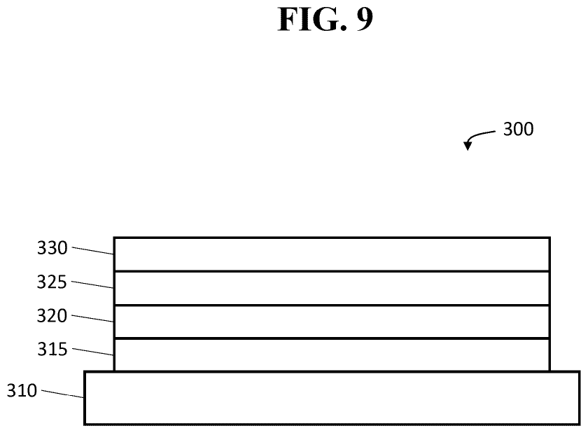

Embodiments of the disclose subject matter may provide a device that includes a plasmonic phosphorescent organic light emitting device (PHOLED) having an anode and a cathode having a thickness of about 5-60 nm. An example plasmonic PHOLED device 300 is shown in FIG. 9, which may include a substrate 310, a cathode 315, an emissive stack 320, an enhancement layer 325, and an anode 330. FIG. 9 merely shows an example arrangement, and other arrangements of the plasmonic PHOLED device may be used.

The device (e.g., device 300) may include an emissive stack (e.g., emissive stack 320) disposed between the anode (e.g., anode 330) and the cathode (e.g., cathode 315) and configured to produce excitons, the emissive stack having a phosphorescent first emissive layer comprising an organic phosphorescent first emissive material. The device may include an enhancement layer (e.g., enhancement layer 325) comprising a plasmonic material exhibiting surface plasmon resonance that non-radiatively couples to at least the organic phosphorescent first emissive material and transfers excited state energy from the non-radiatively-coupled organic phosphorescent first emissive material to non-radiative modes of surface plasmon polaritons. The device may be configured to generate less than 1° C. rise in temperature for every 2.72 mW/cm² of operating power applied to the device, or even generate less than 1° C. rise in temperature for every 2.26 mW/cm² of operating power applied to the device. The enhancement layer may be disposed less than a threshold distance away from the organic phosphorescent first emissive material.

The organic phosphorescent first emissive material may have a total non-radiative decay rate constant k_{non-rad}⁰, a total radiative decay rate constant k_{rad}⁰, a total non-radiative decay rate constant due to the enhancement layer k_{non-rad}^{plasmon}, and a total radiative decay rate constant due to the enhancement layer k_{rad}^{plasmon}. The enhancement layer is disposed not more than a threshold distance from the phosphorescent first emissive layer. The threshold distance may be a distance at which

$$\frac{{k}_{rad}^{plasmon}}{{k}_{non - rad}^{plasmon}} = \frac{{k}_{rad}^{0}}{{k}_{non - rad}^{0}} .$$

The increased emission rate constant of the OLED emitter is strongly dependent on the distance of the emitter from the enhancement layer. Once the emitter is closer than a threshold distance, achieving better performance requires moving the light emitting material closer to the enhancement layer. To achieve a better OLED performance, the preferred distance from the enhancement layer to the organic emissive layer containing the emissive material (“EML”) is not greater than 100 nm, more preferably not greater than 60 nm, and most preferably not greater than 25 nm. In some embodiments and for manufacturability reasons, it may be desirable to have the distance between the enhancement layer and the EML to be 5-100 nm, more preferably 5-60 nm, and most preferably 5-25 nm. Achieving this desired distance between the EML and the enhancement layer may require providing one or more of the various functional OLED layers between the EML and the enhancement layer so that the EML and the enhancement layer are not in direct contact. For example, one may include a hole injection layer between the enhancement layer and the emissive material layer to lower the voltage of operation of the OLED. Various functional OLED layers may be optionally provided between the EML and the enhancement layer. The minimum threshold distance in this embodiment is about 5 nm, as that is about the minimum thickness required for the various materials to form a working functional OLED layer.

Understanding the advantages of using the non-radiative mode of SPP and controlling the distance between the EML and the enhancement layer to be not greater than the threshold distance begins with the decay rate constants of the light emitting material. For any light emitter the Quantum Yield (QY) of photons can be expressed as the ratio of the radiative and non-radiative decay rate constants and is explicitly defined as the number of photons emitted per excited state:

$$QY = \frac{{k}_{rad}^{total}}{{k}_{rad}^{total} + {k}_{non - rad}^{total}} \qquad ( 1 )$$

where k_{rad}^{total} is the sum of all the radiative processes and k_{non-rad}^{total} is the sum of all the non-radiative processes. For an isolated emitter in free space, we can define the molecular radiative and non-radiative decay rate constants, k⁰_{rad} and k⁰_{non-rad}. For the isolated molecule, the Quantum Yield (QY⁰) is:

$${QY}^{0} = \frac{{k}_{rad}^{0}}{{k}_{rad}^{0} + {k}_{non - rad}^{0}} \qquad ( 2 )$$

However, in an optoelectronic device, such as an OLED, there are a number of other processes which affect the total radiative and non-radiative decay rate constants. Some of these are energy transfer to the radiative and non-radiative decay modes of the surface plasmon in a plasmonic material such as a metal. These modes become important when the light emitting material is in the vicinity of the plasmonic material. This may lead to increased values for both the total radiative decay rate constant and total non-radiative decay rate constant in the presence of a plasmonic material. In the quantum yield, these additional processes can be specifically accounted for:

$$QY = \frac{{k}_{rad}^{total}}{{k}_{rad}^{total} + {k}_{non - rad}^{total}} = \frac{{k}_{rad}^{0} + {k}_{rad}^{plasmon}}{{k}_{rad}^{0} + {k}_{rad}^{plasmon} + {k}_{non - rad}^{0} + {k}_{non - rad}^{plasmon}} \qquad ( 3 )$$

where k_{rad}^{plasmon} and k_{non-rad}^{plasmon} are the radiative and non-radiative decay rate constants, respectively, for the light emitter when interacting with the SPP.

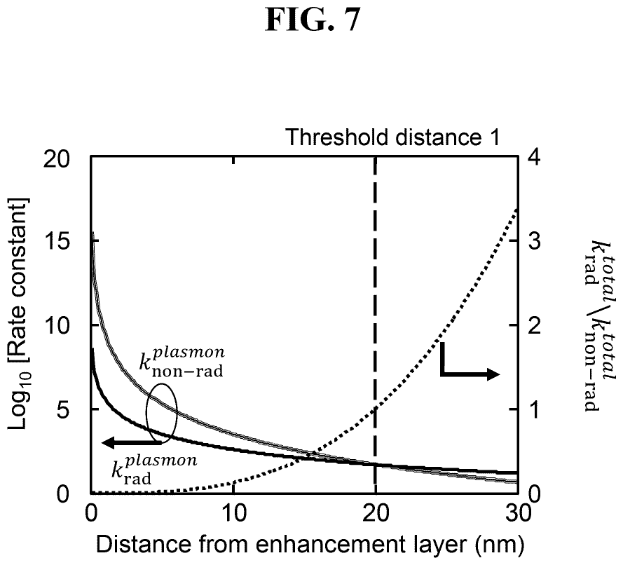

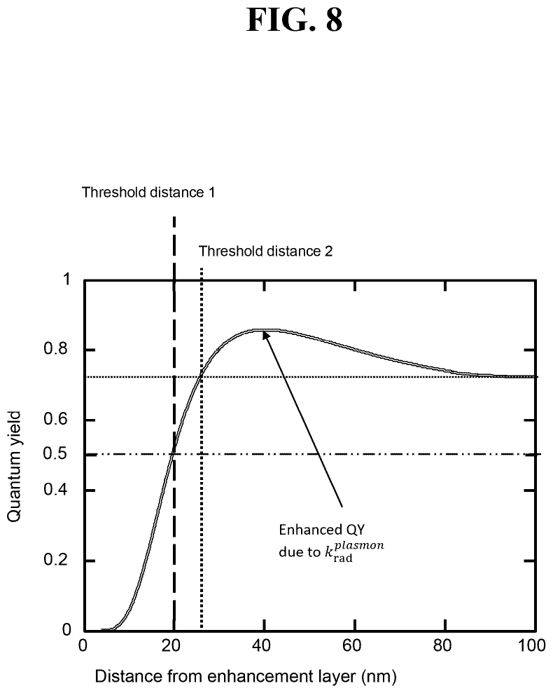

A qualitative plot of k_{rad}^{plasmon} and k_{non-rad}^{plasmon} as a function of the light emitter's distance from an enhancement layer such as a metallic film is shown in FIG. 7. For distances close to the enhancement layer, k_{rad}^{total} will be dominated by the k_{rad}^{plasmon} term and k_{non-rad}^{total} will be dominated by k_{non-rad}^{plasmon}. Thus, FIG. 7 also describes the total radiative and non-radiative decay rates. This is shown on the right axis of FIG. 7 which is the ratio of the total radiative decay rate constant, k_{rad}^{total}, to the total non-radiative decay rate constant, k_{non-rad}^{total}. As is shown on the left axis of FIG. 3, the two plasmon based decay rate constants have different functional dependencies on the distance of the emitter from the metallic layer (in this case 1/r\hat{ }6 for the non-radiative and 1/r\hat{ }3 for the radiative rate). The different dependencies on distance from the enhancement layer results in a range of distances over which the radiative decay rate constant is the largest rate constant due to the interactions with the surface plasmon. For distances within this particular range, the photon yield is increased over the photon yield of an isolated molecule without the enhancement layer, increasing the QY. This is illustrated in the plot FIG. 8 in which quantum yield is plotted as a function of light emitting material's distance from the metallic film. Once the non-radiative decay rate constant becomes near in value to the radiative decay rate the QY starts to drop, creating a peak in the QY at some specific distance.

For a given pair of light emitting material and enhancement layer, there may be a total non-radiative decay rate constant and a total radiative decay rate constant. As the light emitting material layer becomes closer to the enhancement layer, the non-radiative decay rate constant grows more rapidly than the radiative decay rate constant. At some distance, the total non-radiative decay rate constant of the light emitting material in the presence of the enhancement layer may be equal to the total radiative decay rate constant of the light emitting material in the presence of the enhancement layer. This may be referred to herein as the Threshold Distance 1. Threshold Distance 1 may be the distance the light emitting layer is from the enhancement layer at which the following statement holds:

$${k}_{non - rad}^{plasmon} + {k}_{non - rad}^{0} = {k}_{rad}^{plasmon} + {k}_{rad}^{0} \qquad ( 4 )$$

For distances closer to the enhancement layer than the Threshold Distance 1 the total non-radiative decay rate may be larger than the radiative decay rate and the quantum yield may be less than 0.5 or 50%. For these distances, there may be an even larger speed-up in the rate at which energy leaves the light emitter as the non-radiative decay rate constant exceeds the radiative decay rate constant. The enhancement layer-to-emitter distances less than or equal to the Threshold Distance 1 may satisfy the following condition:

$${k}_{non - rad}^{plasmon} \geq {k}_{rad}^{plasmon} + {k}_{rad}^{0} - {k}_{non - rad}^{0} \qquad ( 5 )$$

For distances larger than Threshold Distance 1 the total radiative decay rate constant may be larger than the total non-radiative decay rate constant, however, the quantum yield of the light emitting material is reduced over the case when the enhancement layer is not present. Thus, the light emitter may still be quenched, a process which is avoided in typical opto-electronic devices but may be part of embodiments of the disclosed subject matter.

The distance of the emitter from the enhancement layer at which quenching starts may be defined herein as the Threshold Distance 2. At this distance, the QY of the light emitter in the presence and absences of the enhancement layer may be identical. When the light emitter is moved closer to the enhancement layer, the QY may drop. Threshold Distance 2 may be the distance the light emitting layer is from the enhancement layer at which the following statement holds:

$${QY}^{0} = QY , \qquad ( 6 )$$

[1] where QY⁰ is the light emitting materials intrinsic quantum yield and QY is the quantum yield with the enhancement layer. This leads to the following expression when accounting for the radiative and non-radiative decay rate constants due to the plasmonic material of the enhancement layer:

$$\frac{{k}_{rad}^{0}}{{k}_{rad}^{0} + {k}_{non - rad}^{0}} = \frac{{k}_{rad}^{0} + {k}_{rad}^{plasmon}}{{k}_{rad}^{0} + {k}_{non - rad}^{0} + {k}_{rad}^{plasmon} + {k}_{non - rad}^{plasmon}} \qquad ( 7 )$$

[2] Solving the k_{non-rad}^{plasmon} we obtain the following expression for the decay rate constants at Threshold Distance 2:

$${k}_{non - rad}^{plasmon} = \frac{{k}_{non - rad}^{0}}{{k}_{rad}^{0}} \cdot {k}_{rad}^{plasmon} \qquad ( 8 )$$

[3] Conceptually Threshold Distance 2 may be more easily understood from the value of the quantum yield being equal to the value of the quantum yield of the light emitting material without the enhancement layer. See FIG. 8.

Whether the Threshold Distance 1 or Threshold Distance 2 are considered, the physical values of the threshold distances may depend on a number of factors including the frequency of the surface plasmon polariton, oscillator strength of the light emitting material, and the dielectric constant of the light emitting material layer. Therefore, by selecting a suitable set of materials for the organic light emitting material and the plasmonic material of the enhancement layer, the threshold distance may be adjusted.

The cathode of the device may include a film of Ag, where the thickness of the cathode is 5 nm-45 nm. Alternatively, the thickness of the cathode may range from 5 nm up to 200 nm, 5 nm up to 150 nm, 5 nm up to 100 nm, 5 nm up to 75 nm, 5 nm up to 60 nm, 5 nm up to 45 nm, 15 nm up to 45 nm, and may preferably range from 25 nm up to 35 nm for Ag. In some embodiments, the device may include an outcoupling layer. The emissive stack of the device may include at least two emissive layers disposed over one another. The device may be a lighting panel and/or a full color display.

The device may be configured to generate not more than a 5° C. rise in operating temperature when operating at a power density of 11.4 mW/cm² or 13.6 mW/cm². The device may be a display, and the plasmonic PHOLED may be configured to have not more than a 1° C. rise in operating temperature for a luminance of 268 nits increase in display luminance, and 320 nits increase in display luminance. The device may be a display and may be configured to operate at a white point luminance of greater than 1,340 nits, greater than 1,400 nits, greater than 1,500 nits, and/or greater than 1,600 nits. Red, green, and/or blue light may be mixed in a display to produce white light at a fixed standard or color temperature such as D65, where the color temperature of the white light may be, for example, 6500K.

In the device, INC*OUTC>1−INC, where INC may be the fraction of excitons generated in the at least one emissive layer of the emissive stack that couple to one or more plasmon modes in the cathode, and OUTC may be the fraction of plasmons outcoupled as photons emitted outside of the emissive stack. The device may have INC 80%. In some embodiments, the device may have INC 60%.

The emissive stack may be configured to have a first peak photon density inside of the emissive stack that is lower than a second peak photon density outside of the emissive stack when the device is emitting light. The first peak photon density inside of the emissive stack may be lower than half of the second peak photon density outside of the emissive stack.

An external quantum efficiency of the plasmonic PHOLED of the device may be greater than 35%. In some embodiments, a first emissive layer of the at least one emissive layer of the device may have an excited state duration that is less than 20%, 25%, 30%, 35%, 40%, 45%, 50%, 55%, or 60% of a predetermined excited state duration. This predetermined value may be for a conventional emissive layer having an aluminum cathode and an electron transport layer having a thickness of at least 35 nm. In some embodiments, a difference between the plasmonic PHOLED that is configured to have external quantum efficiency of greater than 35% and an excited state lifetime that is selected from the group consisting of: less than 20%, less than 25%, less than 30%, less than 35%, less than 40%, less than 45%, less than 50%, less than 55%, or less than 60% than a predetermined excited state lifetime value.

In some embodiments, a first emissive layer of the at least one emissive layer of the device may have an excited state duration that is less than 20%, 25%, 30%, 35%, 40%, 45%, 50%, 55%, or 60% of a predetermined excited state value or duration. In an embodiment, the predetermined value or duration is the excited state lifetime of the emitter at 1% in PMMA. A thin film of the emitter in PMMA is formed on quartz by drop casting filtered solutions of 1% emitter with PMMA in toluene onto precleaned quartz substrates. Transient data by multiple methods including by time correlated single photon counting (TCSPC) using a 335 nm NanoLED pulsed excitation source.

As used herein, a Lambertian profile may have a diffuse emission of light with an intensity that is independent of emission angle to within 10% or 20%.

The anode of the emissive stack may be transparent. As used throughout, the emissive stack may be transparent for at least 30%, at least 40%, or at least 60% for any wavelength longer than 400 nm in the visible region of the electromagnetic spectrum. The device may be optically transparent for greater than 40% or greater than 60% for any wavelength longer than 400 nm in the visible region of the electromagnetic spectrum, or have an overall or average transparency that exceeds 40% across the visible spectrum. In some embodiments, the anode of the emissive stack may be reflective. As used throughout, a surface may be reflective when at least 20% or at least 30% of any wavelength longer than 400 nm in the visible region of the electromagnetic spectrum is reflected.

The plasmonic PHOLED of the device may have an external quantum efficiency that is greater than 35%, and may have an incoupling of excitons from the at least one emissive layer to plasmon modes in the cathode that is greater than 60%. The device may have an optical transparency of greater than greater than 40% or greater than 60% across a visible spectrum. The anode of the device may be reflective. The emissive stack of the plasmonic PHOLED may have at least a first side and a second side, where the device is configured to emit light from the first side and is configured to have a Lambertian emission profile of light.

Embodiments described herein may be found in devices that have pixels that include one or more sub-pixels. Embodiments described herein may be found in at least one of the one or more sub-pixels. In a first embodiment, at least one of the sub-pixels may be in a side-by-side (SBS) architecture. In a SBS architecture, at least one or more emissive layers of each sub-pixel the pixel are different than another sub-pixel in the pixel. Generally, a “Red” sub-pixel will have a red emissive layer and the red emissive layer emits red light and the sub-pixel emits red light. In an embodiment, there may be no color filter or color altering layer in a SBS architecture, although this is not a requirement and a color filter or color altering layer may be used. In a second embodiment, at least one of the sub-pixels may be in a stacked architecture. In a stacked architecture, at least one or more emissive layer is shared between two or more sub-pixels in the pixel. Generally, this is used in a white plus color filter/color altering layer architecture, where the emissive layers in the pixel produce “white” light and different color filter/color altering layer arrangements are used for sub-pixels in the pixel to produce a desired color. For example, the stack could produce “white”, a first sub-pixel could have a red color filter/color altering layer so the first sub-pixel would produce red light and a second sub-pixel could have a green color filter/color altering layer so the second sub-pixel would produced green light. Any color filtering/altering may be used to produce any color light. Additionally, the stack does not necessarily need to produce a “white” light and can produce any color light. Devices may be made that are a mixture of both SBS and stack architecture to produce pixel/sub-pixel design that includes some or all of the embodiments described. Embodiments of the present invention may be included in one or more of a SBS or stacked pixel/sub-pixel design.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A device comprising:
a plasmonic phosphorescent organic light emitting device (PHOLED) comprising:
an anode;
a cathode having a thickness of about 5-100 nm;
an emissive stack disposed between the anode and the cathode and configured to produce excitons, the emissive stack comprising a phosphorescent first emissive layer comprising an organic phosphorescent first emissive material;
an enhancement layer comprising a plasmonic material exhibiting a surface plasmon resonance that non-radiatively couples to at least the organic phosphorescent first emissive material and transfers excited state energy from the first emissive material to non-radiative modes of the plasmonic material,
wherein the device is configured to generate less than 1° C. rise in temperature for every 2.26 mW/cm² of operating power applied to the device.

2. The device of claim 1, wherein the enhancement layer is disposed less than a threshold distance away from the organic phosphorescent first emissive material.

3. The device of claim 1, wherein the organic phosphorescent first emissive material has a total non-radiative decay rate constant k_{non-rad}⁰, a total radiative decay rate constant k⁰_{rad}, a total non-radiative decay rate constant due to the enhancement layer k_{non-rad}^{plasmon}, and a total radiative decay rate constant due to the enhancement layer k_{rad}^{plasmon},
wherein the enhancement layer is disposed not more than a threshold distance from the phosphorescent first emissive layer, and
wherein the threshold distance is a distance at which
$$\frac{{k}_{rad}^{plasmon}}{{k}_{non - rad}^{plasmon}} = \frac{{k}_{rad}^{0}}{{k}_{non - rad}^{0}} .$$

4. The device of claim 1, wherein
$$INC * OUTC > 1 - INC ,$$
wherein
INC is the fraction of excitons generated in the at least one emissive layer of the emissive stack that couple to one or more plasmon modes in the cathode, and
OUTC is the fraction of plasmons outcoupled as photons emitted outside of the emissive stack.

5. The device of claim 1, wherein the cathode comprises a film of Ag, wherein the thickness of the cathode is 5 nm-45 nm.

6. The device of claim 1, wherein the device is configured to generate not more than a 5° C. rise in operating temperature when operating at a power density selected from a group consisting of: 11.4 mW/cm², and 13.6 mW/cm².

7. The device of claim 1, wherein the device is a display, and wherein the plasmonic PHOLED is configured to have not more than a 1° C. rise in operating temperature for a luminance selected from the group consisting of: 268 nits increase in display luminance, and 320 nits increase in display luminance.

8. (canceled)

9. The device of claim 1, wherein the device is a display and is configured to operate at a white point luminance selected from a group consisting of: greater than 1,340 nits, greater than 1,400 nits, greater than 1,500 nits, and greater than 1,600 nits.

10. (canceled)

11. (canceled)

12. The device of claim 1, wherein
$$INC \geq 60 \% ,$$
and
wherein INC is the fraction of excitons generated in the at least one emissive layer of the emissive stack that couple to one or more plasmon modes in the cathode.

13. (canceled)

14. (canceled)

15. The device of claim 1, wherein an external quantum efficiency of the plasmonic PHOLED is greater than 35%.

16. The device of claim 1, wherein a first emissive layer of the at least one emissive layer has an excited state duration that selected from the group consisting of: less than 20%, less than 25%, less than 30%, less than 35%, less than 40%, less than 45%, less than 50%, less than 55%, or less than 60% of a predetermined excited state duration.

17. (canceled)

18. (canceled)

19. (canceled)

20. The device of claim 1, wherein the device has an optical transparency of greater than 40% or greater than 60% across a visible spectrum.

21. (canceled)

22. The device of claim 1, wherein the plasmonic PHOLED has an external quantum efficiency that is greater than 35%, and has an incoupling of excitons from the at least one emissive layer to plasmon modes in the cathode that is greater than 60%.

23. (canceled)

24. (canceled)

25. (canceled)

26. The device of claim 1, wherein the device is a lighting panel.

27. The device of claim 1, wherein the device is a full color display.

28. A consumer electronic device comprising:
a plasmonic phosphorescent organic light emitting device (PHOLED) comprising:
an anode;
a cathode having a thickness of about 5-100 nm;
an emissive stack disposed between the anode and the cathode and configured to produce excitons, the emissive stack comprising a phosphorescent first emissive layer comprising an organic phosphorescent first emissive material;
an enhancement layer comprising a plasmonic material exhibiting a surface plasmon resonance that non-radiatively couples to at least the organic phosphorescent first emissive material and transfers excited state energy from the first emissive material to non-radiative modes of the plasmonic material,
wherein the device is configured to generate less than 1° C. rise in temperature for every 2.26 mW/cm² of operating power applied to the device.

29. The consumer electronic device of claim 28, wherein the device is at least one type selected from the group consisting of: a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, an automotive display, a video walls comprising multiple displays tiled together, a theater or stadium screen, and a sign.

30. The device of claim 1, wherein the cathode has a thickness selected from at least one of a group consisting of: 5-200 nm, 5-150 nm, 5-100 nm, 5-75 nm, 5-60 nm, 5-45 nm, 15-45 nm, and 25-35 nm.

31. The device of claim 1, wherein the device is configured to generate less than 1° C. rise in temperature for every 2.72 mW/cm² of operating power applied to the device.

32. (canceled)

33. (canceled)

34. The device of claim 1, wherein
$$INC * OUTC > 1 - INC ,$$
wherein
INC is the is the number of excitons from the emissive layer of the emissive stack coupled to the plasmon mode in the cathode divided by the total number of excitons in the emissive layer of the emissive stack, and
OUTC is the number of plasmons outcoupled to photons outside of the emissive stack divided by the total number of excitons in the emissive layer of the emissive stack.
